(19) United States
(12) Patent Application Publication
(10) Pub. No.: US 2011/0169542 A1
(43) Pub. Date: Jul. 14, 2011

(54) DELAY CIRCUIT OF SEMICONDUCTOR MEMORY APPARATUS AND METHOD FOR DELAYING

(75) Inventors: Jae Bum KO, Ichon-shi (KR); Jong Chern LEE, Ichon-shi (KR); Sang Jin BYEON, Ichon-shi (KR)

(73) Assignee: Hynix Semiconductor Inc., Ichon-shi (KR)

(21) Appl. No.: 12/839,352

(22) Filed: Jul. 19, 2010

(30) Foreign Application Priority Data
Jan. 8, 2010 (KR) 10-2010-0001774

(51) Int. Cl. H03H 11/26

(52) U.S. Cl. 327/276

(57) ABSTRACT

A delay circuit of a semiconductor memory apparatus includes a decoding unit configured to decode a plurality of test signals and enable one of a plurality of control signals; a bias voltage generation unit configured to generate a first bias voltage and a second bias voltage depending upon the control signal enabled among the plurality of control signals; and a delay unit configured to determine a delay time depending upon levels of the first and second bias voltages, delay an input signal by the determined delay time, and output a resultant signal as an output signal.

### CROSS-REFERENCES TO RELATED APPLICATION

The present application claims priority under 35 U.S.C §119(a) to Korean Application No. 10-2010-0001774, filed on Jan. 8, 2010, in the Korean Intellectual Property Office, which is incorporated herein by reference in its entirety as if set forth in full.

### BACKGROUND

1. Technical Field

The present invention relates to a semiconductor integrated circuit, and more particularly, to a delay circuit of a semiconductor memory apparatus.

2. Related Art

A typical semiconductor memory apparatus includes a delay circuit for delaying an input signal to output the delayed input signal as an output signal.

FIG. 1 is a circuit diagram illustrating a conventional delay circuit of a semiconductor memory apparatus. Referring to FIG. 1, the conventional delay circuit of a semiconductor memory apparatus includes first through sixteenth transistors P1-P8 and N1-N8, first through fourth inverters IV1-IV4, first through fourth capacitors C1-C4, and first and second resistors R1 and R2.

In a conventional delay circuit of a semiconductor memory apparatus as shown in FIG. 1, the delay time is determined based on first through third test signals TM0-TM2. An input signal ‘in’ is delayed by the determined delay time, and a resultant signal is outputted as an output signal ‘out’.

As a large number of delay circuits configured as described above are disposed in a semiconductor memory apparatus, the area-efficiency of the semiconductor memory apparatus is degraded.

### SUMMARY

It is therefore an object of the present invention to provide a delay circuit of a semiconductor memory apparatus which can improve the area-efficiency of a semiconductor memory apparatus.

In one exemplary embodiment of the present invention, a delay circuit of a semiconductor memory apparatus includes: a decoding unit configured to decode a plurality of test signals and enable one of a plurality of control signals; a bias voltage generation unit configured to generate a first bias voltage and a second bias voltage based upon the control signal enabled among the plurality of control signals; and a delay unit configured to determine a delay time based upon the first and second bias voltage levels, delay an input signal by the determined delay time, and output a resultant signal as an output signal.

In another exemplary embodiment, a delay circuit of a semiconductor memory apparatus includes: a bias voltage generation unit configured such that a second bias voltage level becomes lower as a first bias voltage level gets higher and the level of the second bias voltage becomes higher as the level of the first bias voltage gets lower, in response to a control signal; and a plurality of voltage response type delay units configured to determine delay times based upon the first and second bias voltage levels.

In still another exemplary embodiment, a method for delaying in a semiconductor memory apparatus comprises: decoding a plurality of test signals and enable one of a plurality of control signals; generating a first bias voltage and a second bias voltage based upon the enabled control signal; and determining a delay time based upon the first and second bias voltage levels, delaying an input signal by the determined delay time, and outputting a resultant signal as an output signal.

### BRIEF DESCRIPTION OF THE DRAWINGS

Features, aspects, and embodiments are described in conjunction with the attached drawings, in which:

FIG. 1 is a circuit diagram illustrating a conventional delay circuit of a semiconductor memory apparatus;

FIG. 2 is a block diagram schematically illustrating a delay circuit of a semiconductor memory apparatus in accordance with an embodiment of the present invention;

FIG. 3 is a circuit diagram illustrating the bias voltage generation unit shown in FIG. 2;

FIG. 4 is a circuit diagram illustrating the voltage response type delay unit shown in FIG. 2; and

FIG. 5 is a block diagram illustrating the delay circuit in accordance with an embodiment of the present invention.

### DETAILED DESCRIPTION

Hereinafter, a delay circuit of a semiconductor memory apparatus according to the present invention will be described below with reference to the accompanying drawings through exemplary embodiments.

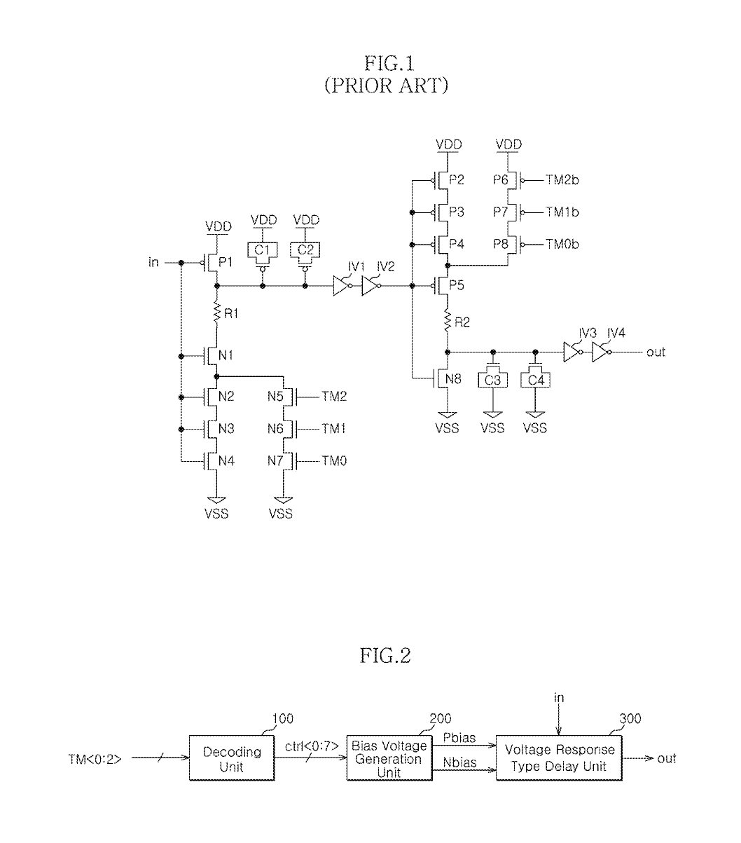

FIG. 2 is a block diagram schematically illustrating a delay circuit of a semiconductor memory apparatus in accordance with an embodiment of the present invention. Referring to FIG. 2, the delay circuit includes a decoding unit 100, a bias voltage generation unit 200, and a voltage response type delay unit 300.

The decoding unit 100 is configured to decode first through third test signals TM<0:2> and enable one of first through eighth control signals ctrl<0:7>. The first through third test signals TM<0:2> are the ones inputted from test equipment whose levels are determined by fuse cutting after the test.

The bias voltage generation unit 200 is configured to generate first and second bias voltages Pbias and Nbias in response to a control signal ctrl<i> enabled from among the first through eighth control signals ctrl<0:7>. The bias voltage generation unit 200 is configured such that the level of the second bias voltage Nbias is relatively low if the level of the first bias voltage Pbias is high, whereas the level of the second bias voltage Nbias is relatively high if the level of the first bias voltage Pbias is low.

The voltage response type delay unit 300 is configured to determine a delay time based upon the levels of the first and second bias voltages Pbias and Nbias, delay an input signal ‘in’ by the determined delay time, and output a resultant signal as an output signal ‘out’. The voltage response type delay unit 300 is configured such that the delay time is long if the level of the first bias voltage Pbias is relatively high and the level of the second bias voltage Nbias is relatively low, whereas the delay time is short if the level of the first bias voltage Pbias is relatively low and the level of the second bias voltage Nbias is relatively high.

Since the decoding unit 100 is configured in the same manner as a conventional decoding unit, detailed description thereof will be omitted.

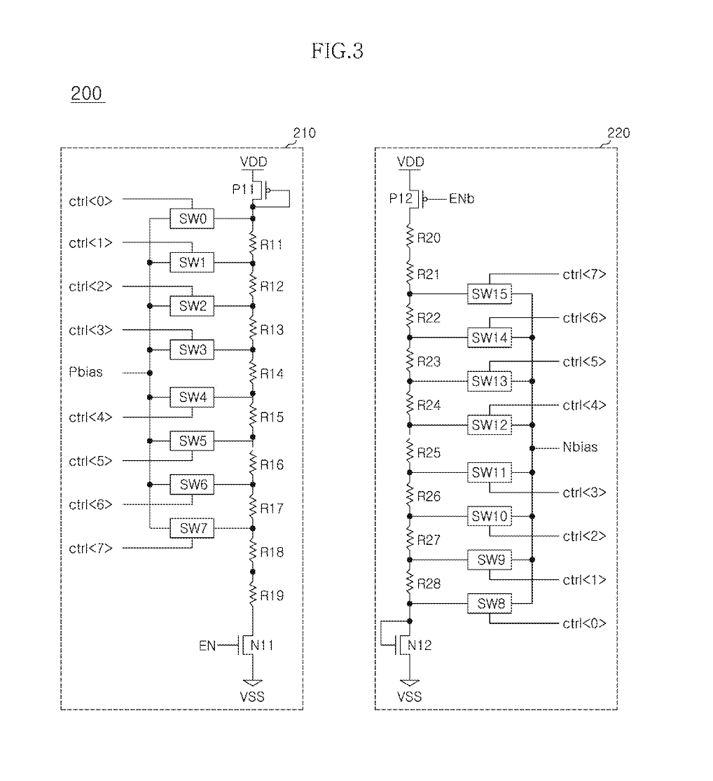

FIG. 3 is a circuit diagram illustrating the bias voltage generation unit shown in FIG. 2. Referring to FIG. 3, the bias voltage generation unit 200 includes a first bias voltage generation section 210 and a second bias voltage generation section 220.

The first bias voltage generation section 210 includes first and second transistors P11 and N11, first through ninth resistors R11-R19, and first through eighth switching elements SW0-SW7.

The first transistor P11 has a source to which an external voltage VDD is applied, and a gate and a drain coupled with each other. The second transistor N11 has a gate, which receives an enable signal EN, and a source to which a ground terminal VSS is coupled. The first through ninth resistors R11-R19 are coupled in series between the drain of the first transistor P11 and the drain of the second transistor N11. The first switching element SW0 has an input terminal that is coupled to the node disposed between the first transistor P11 and the first resistor R11, and is turned on or off in response to the first control signal ctrl<0>. The second switching element SW1 has an input terminal that is coupled to the node disposed between the first resistor R11 and the second resistor R12, and is turned on or off in response to the second control signal ctrl<1>. The third switching element SW2 has an input terminal that is coupled to the node disposed between the second resistor R12 and the third resistor R13, and is turned on or off in response to the third control signal ctrl<2>. The fourth switching element SW3 has an input terminal that is coupled to the node disposed between the third resistor R13 and the fourth resistor R14, and is turned on or off in response to the fourth control signal ctrl<3>. The fifth switching element SW4 has an input terminal that is coupled to the node disposed between the fourth resistor R14 and the fifth resistor R15, and is turned on or off in response to the fifth control signal ctrl<4>. The sixth switching element SW5 has an input terminal that is coupled to the node disposed between the fifth resistor R15 and the sixth resistor R16, and is turned on or off in response to the sixth control signal ctrl<5>. The seventh switching element SW6 has an input terminal that is coupled to the node disposed between the sixth resistor R16 and the seventh resistor R17, and is turned on or off in response to the seventh control signal ctrl<6>. The eighth switching element SW7 has an input terminal that is coupled to the node disposed between the seventh resistor R17 and the eighth resistor R18, and is turned on or off in response to the eighth control signal ctrl<7>. The first bias voltage Pbias is outputted from a node that is commonly coupled to the output terminals of the first through eighth switching elements SW0-SW7.

The second bias voltage generation section 220 includes third and fourth transistors P12 and N12, tenth through eighteenth resistors R20-R28, and ninth through sixteenth switching elements SW8 through SW15.

The third transistor P12 has a gate that receives an inverted enable signal ENb and a source to which the external voltage VDD is applied. The fourth transistor N12 has a gate and a drain that are coupled with each other and a source to which the ground terminal VSS is coupled. The tenth through eighteenth resistors R20-R28 are coupled in series between the drain of the third transistor P12 and the drain of the fourth transistor N12. The ninth switching element SW8 has an input terminal that is coupled to the node disposed between the fourth transistor N12 and the eighteenth resistor R28, and is turned on or off in response to the first control signal ctrl<0>. The tenth switching element SW9 has an input terminal that is coupled to the node disposed between the eighteenth resistor R28 and the seventeenth resistor R27, and is turned on or off in response to the second control signal ctrl<1>. The eleventh switching element SW10 has an input terminal that is coupled to the node disposed between the seventeenth resistor R27 and the sixteenth resistor R26, and is turned on or off in response to the third control signal ctrl<2>. The twelfth switching element SW11 has an input terminal that is coupled to the node disposed between the sixteenth resistor R26 and the fifteenth resistor R25, and is turned on or off in response to the fourth control signal ctrl<3>. The thirteenth switching element SW12 has an input terminal that is coupled to the node disposed between the fifteenth resistor R25 and the fourteenth resistor R24, and is turned on or off in response to the fifth control signal ctrl<4>. The fourteenth switching element SW13 has an input terminal that is coupled to the node disposed between the fourteenth resistor R24 and the thirteenth resistor R23, and is turned on or off in response to the sixth control signal ctrl<5>. The fifteenth switching element SW14 has an input terminal that is coupled to the node disposed between the thirteenth resistor R23 and the twelfth resistor R22, and is turned on or off in response to the seventh control signal ctrl<6>. The sixteenth switching element SW15 has an input terminal that is coupled to the node disposed between the twelfth resistor R22 and the eleventh resistor R21, and is turned on or off in response to the eighth control signal ctrl<7>. The second bias voltage Nbias is outputted from a node that is commonly coupled to the output terminals of the ninth through sixteenth switching elements SW8 through SW15.

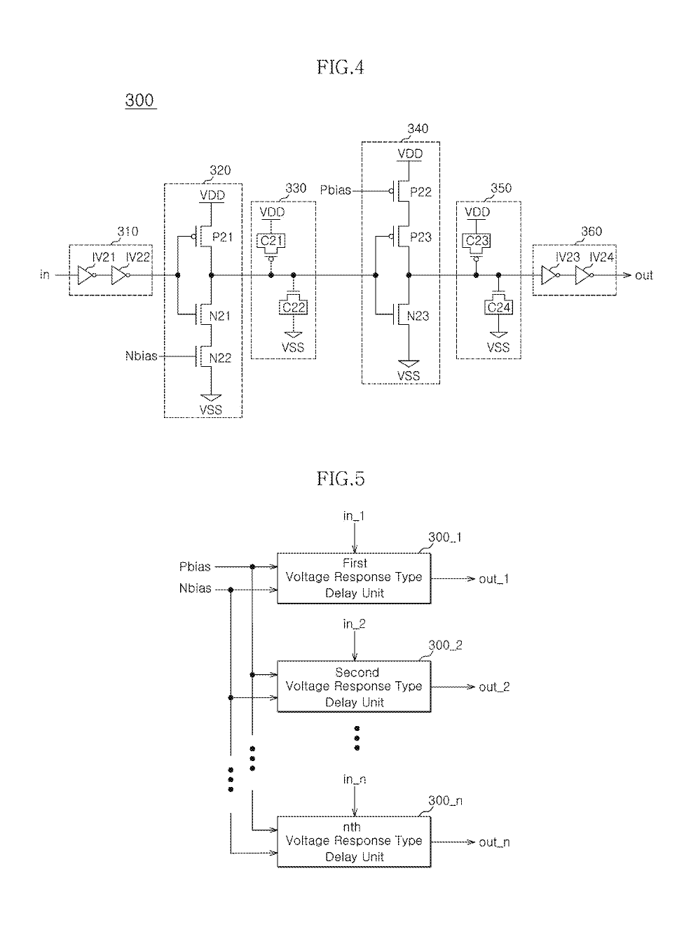

FIG. 4 is a circuit diagram illustrating the voltage response type delay unit shown in FIG. 2. Referring to FIG. 4, the voltage response type delay unit 300 includes first and second driving sections 310 and 360, first and second transition control sections 320 and 340, and first and second signal stabilization sections 330 and 350.

The first driving section 310 is configured to drive the input signal ‘in’ and transfer a resultant signal to the first transition control section 320. In the first driving section 310, first and second inverters IV21 and IV22 are coupled in series.

The first transition control section 320 is configured to invert the signal outputted from the first driving section 310 and output the inverted signal to the first signal stabilization section 330. The first transition control section 320 controls a time period for the output signal of the first transition control section 320 to transition to a low level, based upon the level of the second bias voltage Nbias. For example, in the first transition control section 320, if the level of the second bias voltage Nbias is relatively high, the time period for the output signal of the first transition control section 320 transitions to the low level is short, whereas if the level of the second bias voltage Nbias is relatively low, the time period necessary for the output signal of the first transition control section 320 to transition to the low level is long. Since the first transition control section 320 inverts the signal outputted from the first driving section 310, the first transition control section 320 outputs the output signal of the first driving section 310 as the inverted signal.

The first transition control section 320 includes fifth through seventh transistors P21, N21 and N22. The fifth transistor P21 has a gate, which receives the output signal of the first driving section 310, and a source to which the external voltage VDD is applied. The sixth transistor N21 has a gate, which receives the output signal of the first driving section 310, and a drain to which the drain of the fifth transistor P21 is coupled. The seventh transistor N22 has a gate to which the second bias voltage Nbias is applied, a drain to which the source of the sixth transistor N21 is coupled, and a source to which the ground terminal VSS is coupled. The fifth and sixth transistors P21 and N21 are coupled to the output terminal of the first transition control section 320.

The first signal stabilization section 330 is configured to reduce noise from the output signal of the first transition control section 320 and transfer a resultant signal to the second transition control section 340.

The first signal stabilization section 330 includes first and second capacitors C21 and C22. The first capacitor C21 has one end to which the external voltage VDD is applied and the other end that is coupled to the node that is coupled with the first transition control section 320 and the second transition control section 340. The second capacitor C22 has one end that is coupled to the node that is coupled with the first transition control section 320 and the second transition control section 340 and the other end to which the ground terminal VSS is coupled.

The second transition control section 340 is configured to invert the signal transferred through the first signal stabilization section 330 and transfer the inverted signal to the second signal stabilization section 350. Through this configuration, the second transition control section 340 controls a time period for the output signal of the second transition control section 340 to transition to a high level, based upon the level of the first bias voltage Pbias. For example, the second transition control section 340 is configured in such a manner that, as the level of the first bias voltage Pbias gets higher, the time period necessary for the output signal of the second transition control section 340 to transition to the high level becomes longer, whereas as the level of the first bias voltage Pbias gets lower, the time period for the output signal of the second transition control section 340 to transition to the high level becomes shorter.

The second transition control section 340 includes eighth through tenth transistors P22, P23 and N23. The eighth transistor P22 has a gate, which receives the first bias voltage Pbias, and a source to which the external voltage VDD is applied. The ninth transistor P23 has a gate, which receives the signal transferred through the first signal stabilization section 330, and a source to which the drain of the eighth transistor P22 is coupled. The tenth transistor N23 has a gate that receives the signal transferred through the first signal stabilization section 330, a drain to which the drain of the ninth transistor P23 is coupled, and a source to which the ground terminal VSS is coupled. The ninth and tenth transistors P23 and N23 are coupled to the output terminal of the second transition control section 340.

The second signal stabilization section 350 is configured to reduce noise from the output signal of the second transition control section 340 and transfer a resultant signal to the second driving section 360.

The second signal stabilization section 350 includes third and fourth capacitors C23 and C24. The third capacitor C23 has one end to which the external voltage VDD is applied and the other end that is coupled to the node that is coupled with the second transition control section 340 and the second driving section 360. The fourth capacitor C24 has one end that is coupled to the node that is coupled with the second transition control section 340 and the second driving section 360 and the other end to which the ground terminal VSS is coupled.

The second driving section 360 is configured to drive the signal transferred through the second signal stabilization section 350 and output a resultant signal as the output signal ‘out’. In the second driving section 360, third and fourth inverters IV23 and IV24 are coupled in series.

The delay circuit of the semiconductor memory apparatus in accordance with the embodiment of the present invention, configured as mentioned above, operates as described below.

First, the operation of the delay circuit of a semiconductor memory apparatus shown in FIG. 2 having a maximum delay time will be explained.

By decoding the first through third test signals TM<0:2>, a combination of the first through third test signals TM<0:2> is inputted such that the first control signal ctrl<0> is enabled among the first through eighth control signals ctrl<0:7>.

As the first control signal ctrl<0> is enabled, the first switching element SW0 is turned on, and the voltage of the node to which the first transistor P11 and the first resistor R11 are coupled is outputted as the first bias voltage Pbias. If the first control signal ctrl<0> is enabled, the first bias voltage generation section 210 outputs a highest voltage level from among the levels of the first bias voltage Pbias.

As the first control signal ctrl<0> is enabled, the ninth switching element SW8 is turned on, and the voltage of the node to which the fourth transistor N12 and the eighteenth resistor R28 are coupled is outputted as the second bias voltage Nbias. If the first control signal ctrl<0> is enabled, the second bias voltage generation section 220 outputs a lowest voltage level from among the levels of the second bias voltage Nbias.

The first and second bias voltages Pbias and Nbias, which are generated only when the first control signal ctrl<0> from among the first through eighth control signals ctrl<0:7> is enabled, are inputted to the voltage response type delay unit 300.

In the voltage response type delay unit 300, the time period for transitioning the input signal ‘in’ to the low level and the time period for transitioning the input signal ‘in’ to the high level are increased to the maximum, and the output signal ‘out’ is outputted through a maximum delay time that the delay circuit of the embodiment can have.

Next, the operation of the delay circuit of a semiconductor memory apparatus shown in FIG. 2 having a minimum delay time will be explained.

By decoding the first through third test signals TM<0:2>, a combination of the first through third test signals TM<0:2> is inputted such that the eighth control signal ctrl<7> is enabled among the first through eighth control signals ctrl<0:7>.

As the eighth control signal ctrl<7> is enabled, the eighth switching element SW7 is turned on, and the voltage of the node to which the seventh resistor R17 and the eighth resistor R18 are coupled is outputted as the first bias voltage Pbias. If the eighth control signal ctrl<7> is enabled, the first bias voltage generation section 210 outputs a lowest voltage level from among the levels of the first bias voltage Pbias.

As the eighth control signal ctrl<7> is enabled, the sixteenth switching element SW15 is turned on, and the voltage of the node to which the eleventh resistor R21 and the twelfth resistor R22 are coupled is outputted as the second bias voltage Nbias. If the eighth control signal ctrl<7> is enabled, the second bias voltage generation section 220 outputs a highest voltage level from among the levels of the second bias voltage Nbias.

The first and second bias voltages Pbias and Nbias, which are generated only when the eighth control signal ctrl<7> from among the first through eighth control signals ctrl<0:7> is enabled, are inputted to the voltage response type delay unit 300.

In the voltage response type delay unit 300, the time period for transitioning the input signal ‘in’ to the low level and the time period for transitioning the input signal ‘in’ to the high level are reduced to the minimum, and the output signal ‘out’ is outputted through a minimum delay time that the delay circuit of the embodiment can have.

FIG. 5 is a block diagram illustrating the delay circuit in accordance with an embodiment of the present invention. In each conventional delay circuit shown in FIG. 1, a configuration in which a delay time is determined based upon a plurality of test signals and a configuration in which an input signal is delayed by the determined delay time are incorporated with each other. Conversely, in the present invention, a control block (including the decoding unit 100 and the bias voltage generation unit 200) for controlling a delay time, and a delay block (including the voltage response type delay unit 300) for delaying an input signal by the delay time determined through the control block and outputting a resultant signal are separately configured. Accordingly, the delay circuit in accordance with the embodiment as shown in FIG. 5 is configured such that a plurality of voltage response type delay units 300_1-300_n can commonly receive the first and second bias voltages Pbias and Nbias as the outputs of the control block (including the decoding unit 100 and the bias voltage generation unit 200), whereby the area-efficiency of a semiconductor memory apparatus may be improved.

While certain embodiments have been described above, it will be understood to those skilled in the art that the embodiments described are by way of example only. Accordingly, the delay circuit of a semiconductor memory apparatus described herein should not be limited based on the described embodiments. Rather, the delay circuit of a semiconductor memory apparatus described herein should only be limited in light of the claims that follow when taken in conjunction with the above description and accompanying drawings.

What is claimed is:

1. A delay circuit of a semiconductor memory apparatus, comprising:
a decoding unit configured to decode a plurality of test signals and enable one of a plurality of control signals;
a bias voltage generation unit configured to generate a first bias voltage and a second bias voltage based upon the enabled control signal; and
a delay unit configured to determine a delay time based upon the first and second bias voltage levels, delay an input signal by the determined delay time, and output a resultant signal as an output signal.

2. The delay circuit according to claim 1, wherein the level of the second bias voltage becomes lower as the level of the first bias voltage gets higher, and the level of the second bias voltage becomes higher as the level of the first bias voltage gets lower.

3. The delay circuit according to claim 2, wherein the bias voltage generation unit comprises:
a first bias voltage generation section configured to generate the first bias voltage in response to the plurality of control signals; and
a second bias voltage generation section configured to generate the second bias voltage in response to the plurality of control signals.

4. The delay circuit according to claim 3, wherein each of the first and second bias voltage generation sections comprises:
a plurality of resistors coupled in series; and
a plurality of switching elements having input terminals that are coupled to nodes to which the resistors are coupled,
wherein a node to which output terminals of the plurality of switching elements are commonly coupled is an output terminal of the bias voltage generation section, and
wherein each of the switching elements is turned on by receiving one of the plurality of control signals.

5. The delay circuit according to claim 1, wherein the delay unit comprises:
a first transition control section configured to invert the input signal, output an inverted signal, and control a transition time for the inverted signal to transition to a low level, based upon the level of the second bias voltage; and
a second transition control section configured to invert the inverted signal, output the output signal, and control a transition time for the output signal to transition to a high level, based upon the level of the first bias voltage.

6. The delay circuit according to claim 5, wherein the delay unit further comprises:
a first driving section configured to drive and transfer the input signal to the first transition control section; and
a second driving section configured to drive and output the output signal.

7. A delay circuit of a semiconductor memory apparatus, comprising:
a bias voltage generation unit configured such that a level of a second bias voltage becomes lower as a level of a first bias voltage gets higher and the level of the second bias voltage becomes higher as the level of the first bias voltage gets lower, in response to a control signal; and
a plurality of voltage response type delay units configured to determine delay times based upon the first and second bias voltage levels.

8. The delay circuit according to claim 7, wherein the bias voltage generation unit comprises:
a first bias voltage generation section configured to generate the first bias voltage in response to the control signal; and
a second bias voltage generation section configured to generate the second bias voltage in response to the control signal.

9. The delay circuit according to claim 8, wherein each of the first and second bias voltage generation sections comprises:
a plurality of resistors coupled in series; and
a plurality of switching elements having input terminals that are coupled to nodes to which the resistors are coupled,
wherein a node to which output terminals of the plurality of switching elements are commonly coupled is an output terminal of the bias voltage generation section, and
wherein each of the switching elements is turned on by receiving one of the plurality of control signals.

10. The delay circuit according to claim 7, wherein each of the voltage response type delay units comprises:
a first transition control section configured to invert the input signal, output an inverted signal, and control a transition time for the inverted signal to transition to a low level, based upon the level of the second bias voltage; and
a second transition control section configured to invert the inverted signal, output the output signal, and control a transition time for the output signal to transition to a high level, based upon the level of the first bias voltage.

11. The delay circuit according to claim 10, wherein each of the voltage response type delay units further comprises:
a first driving section configured to drive and transfer the input signal to the first transition control section; and
a second driving section configured to drive and output the output signal.

12. A method for delaying in a semiconductor memory apparatus, comprising:
decoding a plurality of test signals and enable one of a plurality of control signals;
generating a first bias voltage and a second bias voltage based upon the enabled control signal; and
determining a delay time based upon the first and second bias voltage levels, delaying an input signal by the determined delay time, and outputting a resultant signal as an output signal.

13. The method according to claim 12, wherein the level of the second bias voltage becomes lower as the level of the first bias voltage gets higher, and the level of the second bias voltage becomes higher as the level of the first bias voltage gets lower.

14. The method according to claim 13, wherein generating the first bias voltage and the second bias voltage comprises:
generating the first bias voltage in response to the plurality of control signals; and
generating the second bias voltage in response to the plurality of control signals.

15. The method according to claim 12, wherein delaying the input signal by the determined delay time further comprises:
inverting the input signal, outputting an inverted signal, and controlling a transition time for the inverted signal to transition to a low level, based upon the level of the second bias voltage; and
inverting the inverted signal, outputting the output signal, and controlling a transition time for the output signal to transition to a high level, based upon the level of the first bias voltage.
